(19) United States
(12) Patent Application Publication
(10) Pub. No.: US 2015/0083676 A1
(43) Pub. Date: Mar. 26, 2015

(54) MOUNTING APPARATUS WITH FRAME FOR MOUNTING STORAGE DEVICE

(71) Applicants: HON HAI PRECISION INDUSTRY CO., LTD., New Taipei (TW); HONG FU JIN PRECISION INDUSTRY (ShenZhen) CO., LTD., Shenzhen (CN)

(72) Inventors: WEN-TANG PENG, New Taipei (TW); JIE YANG, Shenzhen (CN)

(73) Assignees: HONG FU JIN PRECISION INDUSTRY (ShenZhen) CO., LTD., Shenzhen (CN); HON HAI PRECISION INDUSTRY CO., LTD., New Taipei (TW)

(21) Appl. No.: 14/101,356

(22) Filed: Dec. 10, 2013

(30) Foreign Application Priority Data
Sep. 23, 2013 (CN) 2013104337081

(51) Int. Cl. H05K 7/14; H05K 7/12; H05K 5/02; H05K 7/18

(52) U.S. Cl. CPC H05K 7/1401; H05K 7/18; H05K 7/12; H05K 5/0221
USPC 211/41.12

(57) ABSTRACT

A frame for a mounting apparatus includes a bottom wall, an end wall, and two cantilevered arms. The end wall extends up from an end of the bottom wall. The arms are connected to the end wall and are located above opposite sides of the bottom wall. The arms are separate from the bottom wall. A pole is formed on an inner side of each arm for engaging in a storage device.

### BACKGROUND

1. Technical Field

The present disclosure relates to an apparatus for mounting storage devices such as data-storage devices.

2. Description of Related Art

Electronic devices, such as computers, are generally equipped with storage devices, such as hard disk drives. Mounting a storage device into an electronic device by using traditional screw-type fasteners requires tools and is time-consuming. That is, the process is inconvenient and inefficient.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an exploded, isometric view of an exemplary embodiment of a mounting apparatus, together with a storage device, wherein the mounting apparatus includes a chassis.

FIG. 2 is an exploded, isometric view of the chassis of FIG. 1.

FIG. 3 is a cross-sectional view corresponding to a line III-III of FIG. 1.

FIG. 4 is an assembled, isometric view of the mounting apparatus and storage device of FIG. 1, showing the assembly in a preliminary state prior to locking

FIG. 5 is similar to FIG. 4, but showing the assembly in a locked state.

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references can mean “at least one.”

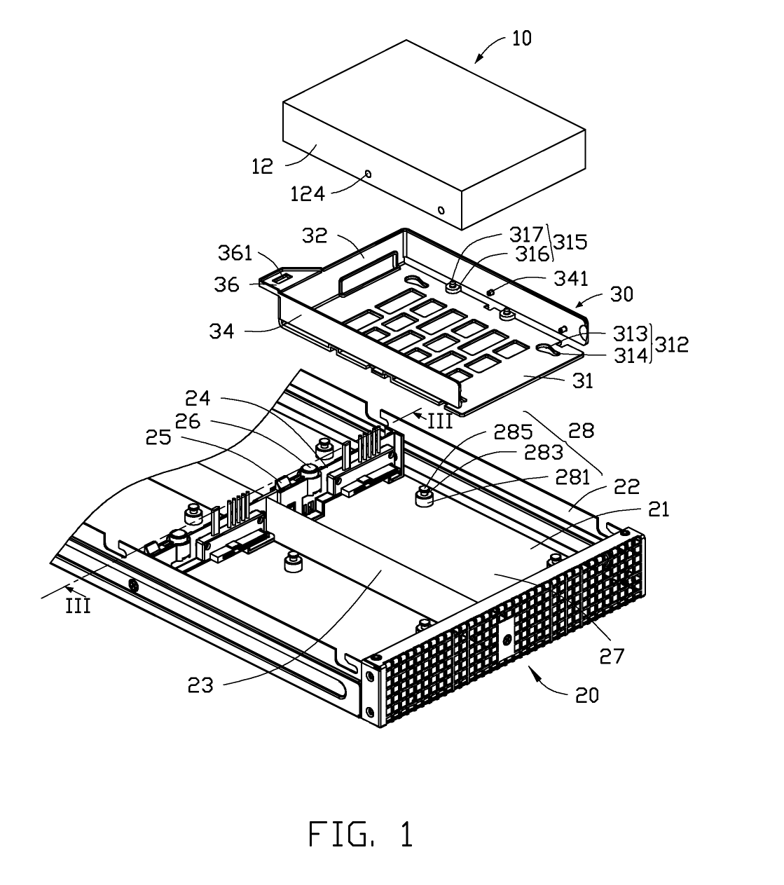

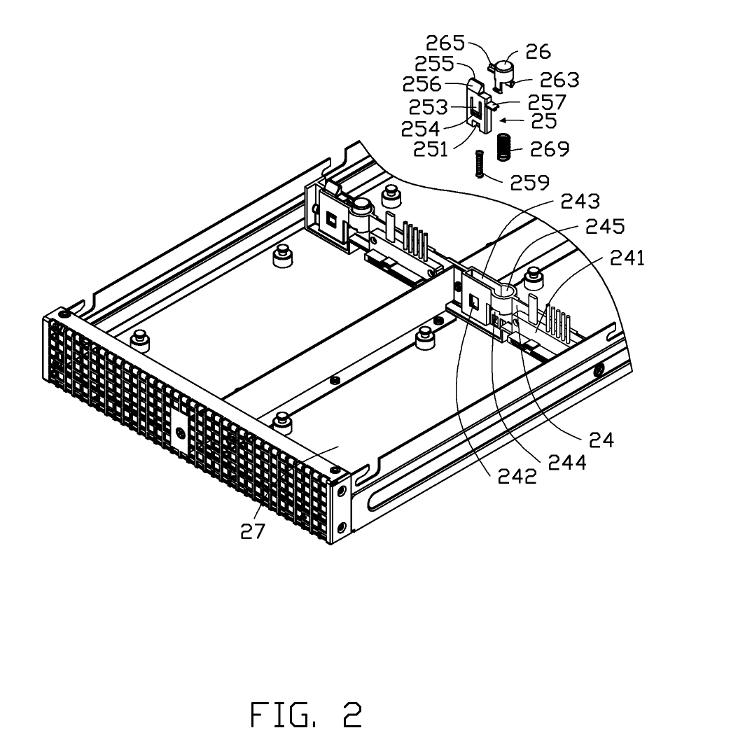

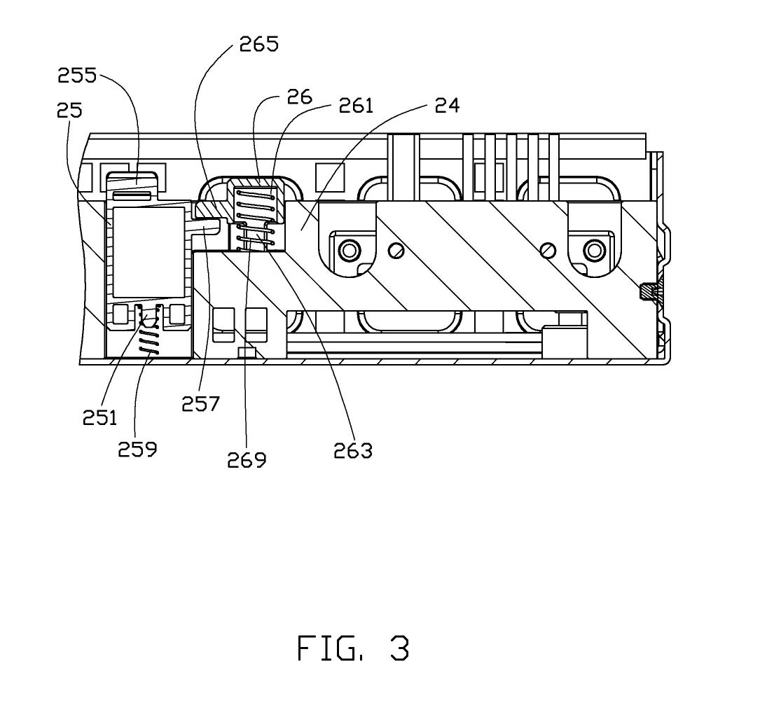

FIGS. 1 to 3 show an exemplary embodiment of a mounting apparatus for a storage device 10. The mounting apparatus includes a chassis 20 and a frame 30. In the embodiment, the storage device 10 is a hard disk drive.

The storage device 10 includes two opposite sidewalls 12. Two spaced fixing holes 124 are defined in each sidewall 12. A pair of holes (not shown) is defined in each of two opposite long sides of the bottom of the storage device 10. Each pair of holes (not shown) is adjacent to the corresponding sidewall 12.

The chassis 20 includes a bottom plate 21, a first side plate 22, a second side plate 23, a connecting device 24, a latch 25, and a button 26. The first side plate 22 perpendicularly extends up from the bottom plate 21. The second side plate 23 perpendicularly extends up from the bottom plate 21, and is parallel to the first side plate 22. The connecting device 24 is perpendicularly connected between the first and second side plates 22 and 23. The latch 25 and the button 26 are mounted to the connecting device 24.

The chassis 20 has a receiving space 27 defined therein. The receiving space 27 is bounded by the bottom plate 21, the first side plate 22, the second side plate 23, and the connecting device 24. Two positioning members 28 protrude up from the bottom plate 21 adjacent to the first side plate 22, and another two positioning members 28 protrude up from the bottom plate 21 adjacent to second side plate 23. Each positioning member 28 includes a post 281 connected to the bottom plate 21, a neck 283 formed on a middle of the top of the post 281, and a head 285 formed on the top of the neck 283. A diameter of the head 285 is greater than a diameter of the neck 283, and less than a diameter of the post 281.

An electrical connector 241 is mounted to the connecting device 24, facing the receiving space 27. A first receiving recess 243 and a second receiving recess 245 are defined in the connecting device 24. Each of the first receiving recess 243 and second receiving recess 245 is open at a top side thereof. A side of the second receiving recess 245 is in communication with the first receiving recess 243. A first slot 242 is defined in a sidewall of the first receiving recess 243. Two second slots 244 are defined in bottoms of opposite sidewalls of the second receiving recess 245, respectively.

The latch 25 is received in the first receiving recess 243, and is slidable up and down in the first receiving recess 243. A protrusion 251 is formed on the middle of the bottom of the latch 25. A first elastic member 259 is received in the first receiving recess 243, with the top of the first elastic member 259 placed around the protrusion 251 and abutting against the bottom of the latch 25. In addition, the bottom of the first elastic member 259 abuts against a bottom wall of the first receiving recess 243. In the illustrated embodiment, the first elastic member 259 is a coil spring. The latch 25 includes a resilient arm 253. A hook 254 is formed on a distal end of the resilient arm 253. The hook 254 extends into the first slot 242, for preventing the latch 25 from sliding out of the first receiving recess 243. A latching portion 255 is formed on the top of the latch 25. The latching portion 255 includes a slanted surface 256 slantingly extending down towards the receiving space 27. An extending arm 257 is formed on a side of the latch 25 and extends into the second receiving recess 245.

The button 26 is received in the second receiving recess 245. A hollow 261 is defined in a middle of the button 26. The hollow 261 is open at a bottom end of the button 26. A second elastic member 269 is received in the second receiving recess 245, with the top of the second elastic member 269 received in the hollow 261, and the bottom of the second elastic member 269 abutting against a bottom wall of the second receiving recess 245. In the embodiment, the second elastic member 269 is a coil spring. The button 26 includes two resilient feet 263 extending into the second slots 244, for preventing the button 26 from sliding out of the second receiving recess 245. A pressing arm 265 is formed on a side of the button 26, and points toward the first receiving recess 243. The pressing arm 265 is located over the extending arm 257.

The frame 30 is a single monolithic body of the one same material formed by molding. Typically, the frame 30 is integrally formed of plastic material, and includes a bottom wall 31, an end wall 32 extending perpendicularly up from a first end of the bottom wall 31, and two cantilevered arms 34 perpendicularly extending from opposite ends of the end wall 32 towards a second end of the bottom wall 31 opposite to the first end. In addition, a tab 36 extends from a top of the end wall 32 in a direction away from the second end. The arms 34 are located above opposite long sides of the bottom wall 31, respectively, and are separate from the bottom wall 31. Two spaced poles 341 protrude from an inner side of each arm 34. The poles 341 of each arm 34 point toward the poles 341 of the opposite arm 34. The bottom wall 31 defines two positioning holes 312 near each of the two long sides thereof. Each pair of positioning holes 312 is adjacent to the corresponding arm 34. Each positioning hole 312 includes a large portion 313 nearer to the end wall 32, and a lock portion 314 communicating with the large portion 313 and farther away from the end wall 32. A width of the large portion 313 is greater than a width of the lock portion 314.

The bottom wall 31 forms two fasteners 315 at each of the two long sides thereof. Each pair of fasteners 315 is adjacent to the corresponding arm 34. Each fastener 315 includes a base 316, and a fastening portion 317 extending up from the top of the base 316. A latching slot 361 is defined in the tab 36. The latching slot 361 is a through slot extending through the top and the bottom of the tab 36.

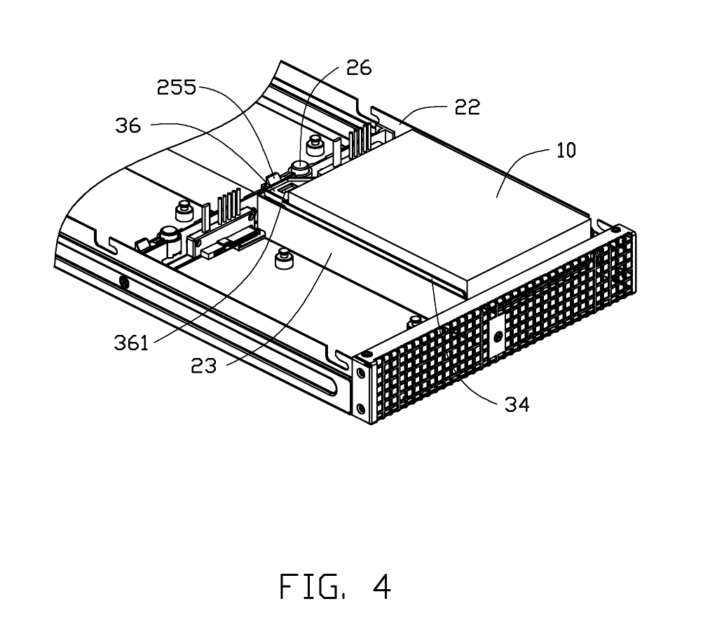

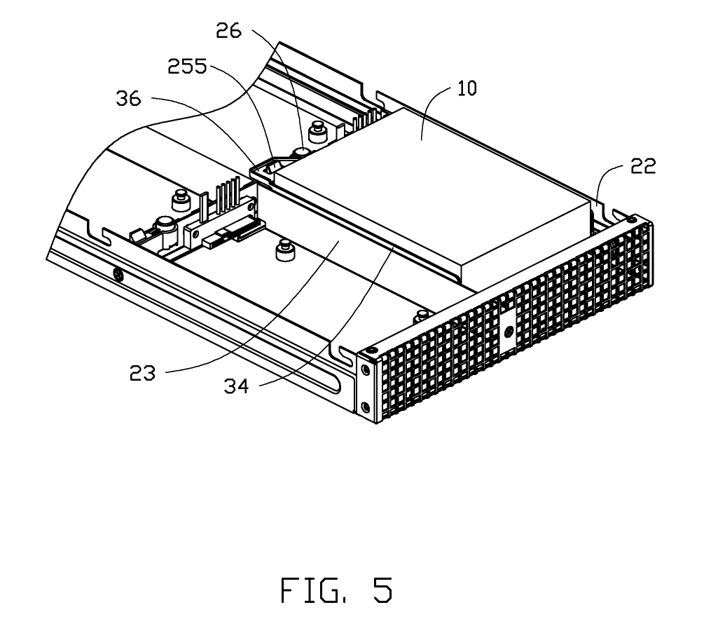

FIGS. 4 and 5 show that in assembly, the arms 34 are elastically deformed away from each other. The storage device 10 is placed in the frame 30. The fastening portions 317 are inserted into the holes of the bottom of the storage device 10, to allow the storage device 10 to be supported on the bases 316. The arms 34 are elastically restored, to allow the poles 341 to engage in the fixing holes 124. The frame 30 is thus combined with the storage device 10.

The frame 30 together with the storage device 10 is located between the first and second side plates 22 and 23, with the tab 36 facing the connecting device 24. The heads 285 extend through the large portions 313, to allow the frame 30 to be supported on the posts 281. The first and second side plates 22 and 23 abut against the arms 34, to allow the poles 341 to become more firmly and securely engaged in the fixing holes 124. The frame 30 is pushed toward the connecting device 24. The necks 283 engage in the lock portions 314, and the heads 253 engage with a top surface of the bottom wall 31. The electrical connector 241 thus extends through the end wall 32 and is connected to the storage device 10. The tab 36 abuts against and rides along the slanted surface 256, and thus pushes the latch 25 down. The first elastic member 259 is compressed. The frame 30 is further pushed toward the connecting device 24. When the latching portion 255 becomes aligned with the latching slot 361, the first elastic member 259 resiliently recovers and pushes the latch 25 up. The latching portion 255 thus engages in the latching slot 361. Thereby, the frame 30 together with the storage device 10 is locked to the chassis 20.

To detach the frame 30, the button 26 is pressed down. The pressing arm 265 presses the extending arm 257 downward, to drive the latch 25 to move down. The latching portion 255 is disengaged from the latching slot 361. The first and second elastic members 259 and 269 are compressed. The frame 30 is pushed away from the connecting device 24, until the necks 283 move into the large portions 313. The electrical connector 241 is thus disconnected from the storage device 10. The first and second elastic members 259 and 269 resiliently recover and push the latch 25 and the button 26 up. The frame 30 is pulled up to be detached from the chassis 20. The arms 34 are elastically deformed away from each other, to allow the poles 341 to exit the fixing holes 124. The storage device 10 is thus detached from the frame 30.

In other embodiments, the button 26 is directly connected to a side of the latch 25. When the button 26 is pressed down, the latch 25 is moved down together with the button 26.

In other embodiments, the positioning members 28 can be omitted; and/or the fasteners 315 can be omitted.

Even though numerous characteristics and advantages of the embodiments have been set forth in the foregoing description, together with details of the structures and the functions of the embodiments, the disclosure is illustrative only, and changes may be made in details, especially in the matters of shape, size, and arrangement of parts within the principles of the embodiments to the full extent indicated by the broad general meaning of the terms in which the appended claims are expressed.

What is claimed is:

1. A frame for a storage device, the frame comprising:
a bottom wall for supporting the storage device;
an end wall extending up from an end of the bottom wall; and
two cantilevered arms connected to the end wall and located above opposite sides of the bottom wall, wherein the arms are separate from the bottom wall, and a pole is formed on an inner side of each arm for engaging in the storage device.

2. The frame of claim 1, wherein the frame is a single monolithic body of plastic material.

3. The frame of claim 1, wherein the bottom wall forms a plurality of fasteners, and each fastener comprises a base for supporting the storage device, and a fastening portion extending up from a top of the base for engaging in a bottom of the storage device.

4. A mounting apparatus for a storage device, the mounting apparatus comprising:
a chassis comprising a bottom plate, two opposite side plates extending up from the bottom plate, and a connecting device between the side plates, wherein the bottom plate, the side plates and the connecting device cooperatively define a receiving space therebetween, a slidable latch comprising a latching portion is located in the connecting device, and a first elastic member is located between the latch and the connecting device; and
a frame comprising a bottom wall, an end wall extending up from an end of the bottom wall, two cantilevered arms connected to the end wall and located above opposite sides of the bottom wall, and a tab extending from a top side of the end wall;
wherein the tab has a latching slot defined therein, the arms are separate from the bottom wall, a pole is formed on an inner side of each arm for engaging in the storage device, the frame is received in the receiving space and located between the side plates, and the latching portion is engagable in the latching slot of the tab; and
when the latching portion is engaged in the latching slot, the latching portion is held in position under urging of the first elastic member.

5. The mounting apparatus of claim 4, wherein the connecting device defines a first receiving recess, the first receiving recess is open at a top side thereof, the latch is received in the first receiving recess, and the first elastic member is located between the bottom of the latch and a bottom wall of the first receiving recess.

6. The mounting apparatus of claim 5, further comprising a button attached to the latch, wherein when the button is pressed, the button moves the latch to drive the latching portion to disengage from the latching slot.

7. The mounting apparatus of claim 6, further comprising a second elastic member, wherein the button comprises a pressing arm pointing towards the latch, the second elastic member is located between the button and the connecting device, when the button is pressed, the pressing arm pushes the latch to drive the latching portion to disengage from the latching slot, and the first and second elastic members are compressed.

8. The mounting apparatus of claim 7, wherein the connecting device further defines second receiving recess communicating with the first receiving recess, the second receiving recess is open at a top side thereof, the button is received in the second receiving recess, and the second elastic member is located between the bottom of the button and a bottom wall of the second receiving recess.

9. The mounting apparatus of claim 8, wherein the latch comprises an extending arm pointing towards the button and located under the pressing arm of the button.

10. The mounting apparatus of claim 4, wherein the latching portion is arranged at a top of the latch and comprises a slanted surface slantingly extending down towards the receiving space.

11. The mounting apparatus of claim 4, wherein the bottom wall of the frame defines a plurality of positioning holes, each positioning hole comprises a large portion nearer to the end wall, and a lock portion communicating with the large portion and farther away from the end wall, a width of the large portion is greater than a width of the lock portion, the bottom plate of the chassis forms a plurality of positioning members, each positioning member comprises a neck, and a head on a top of the neck to extend through a corresponding one of the large portions, when the latching portion engages in the latching slot, the necks engage in the lock portions, and the heads engage with a top surface of the bottom wall, when the latching portion disengages from the latching slot and the frame is moved away from the connecting device, the necks move to the large portions.

12. The mounting apparatus of claim 11, wherein each positioning member further comprises a post connected to the bottom plate to support the frame, the neck is formed on a middle of a top of the post.

13. The mounting apparatus of claim 4, wherein the bottom wall of the frame forms a plurality of fasteners, each fastener comprises a base for supporting the storage device, and a fastening portion extending up from a top of the base for engaging in a bottom of the storage device.

14. The mounting apparatus of claim 4, wherein the frame is a single monolithic body of plastic material.

15. A mounting apparatus for a storage device, the mounting apparatus comprising:
a chassis comprising a bottom plate, two opposite side plates extending up from the bottom plate, and a connecting device between the side plates, wherein the bottom plate, the side plates and the connecting device cooperatively define a receiving space therebetween, a slidable latch comprising a latching portion is located in the connecting device, a button is attached to the latch, and a first elastic member is located between the latch and the connecting device; and
a frame comprising a bottom wall, an end wall extending up from an end of the bottom wall, two cantilevered arms connected to the end wall and located above opposite sides of the bottom wall, and a tab extending from a top side of the end wall;
wherein the tab has a latching slot defined therein, the arms are separate from the bottom wall, a pole is formed on an inner side of each arm for engaging in the storage device, and the frame is received in the receiving space and sandwiched between the side plates;
when the frame is pushed toward the connecting device, the latching portion is snappingly engaged in the latching slot of the tab under urging of the first elastic member, and the frame is locked in position by the latch; and
when the button is pressed, the button moves the latch to drive the latching portion to disengage from the latching slot, and thereby the frame is unlocked.

16. The mounting apparatus of claim 15, wherein the connecting device defines a first receiving recess, the first receiving recess is open at a top side thereof, the latch is received in the first receiving recess, and the first elastic member is located between the bottom of the latch and a bottom wall of the first receiving recess.

17. The mounting apparatus of claim 16, further comprising a second elastic member, wherein the button comprises a pressing arm pointing towards the latch, the second elastic member is located between the button and the connecting device, when the button is pressed, the pressing arm pushes the latch to drive the latching portion to disengage from the latching slot, and the first and second elastic members are compressed.

18. The mounting apparatus of claim 17, wherein the connecting device further defines second receiving recess communicating with the first receiving recess, the second receiving recess is open at a top side thereof, the button is received in the second receiving recess, and the second elastic member is located between the bottom of the button and a bottom wall of the second receiving recess.

19. The mounting apparatus of claim 15, wherein the latching portion is arranged at a top of the latch and comprises a slanted surface slantingly extending down towards the receiving space, when the frame is pushed toward the connecting device, the tab abuts against and rides along the slanted surface, and thus pushes the latch down, the first elastic member is compressed, the frame is further pushed toward the connecting device, when the latching portion becomes aligned with the latching slot, the first elastic member resiliently recovers and pushes the latch up, the latching portion thus engages in the latching slot.

20. The mounting apparatus of claim 15, wherein the bottom wall of the frame defines a plurality of positioning holes, each positioning hole comprises a large portion nearer to the end wall, and a lock portion communicating with the large portion and farther away from the end wall, a width of the large portion is greater than a width of the lock portion, the bottom plate of the chassis forms a plurality of positioning members, each positioning member comprises a neck, and a head on a top of the neck to extend through a corresponding one of the large portions, when the latching portion engages in the latching slot, the necks engage in the lock portions, and the heads engage with a top surface of the bottom wall, when the latching portion disengages from the latching slot and the frame is moved away from the connecting device, the necks move to the large portions.
